(19) United States
(12) Patent Application Publication
(10) Pub. No.: US 2026/0005195 A1
(43) Pub. Date: Jan. 1, 2026

(54) BONDING METHOD WITH LOCATION SPECIFIC PROCESSING

(71) Applicant: Tokyo Electron Limited, Tokyo (JP)

(72) Inventors: Kevin Ryan, Albany, NY (US); Christopher Michael Netzband, Albany, NY (US); Chimaobi Mbanaso, Chaska, MN (US); Adam J. Gildea, Albany, NY (US)

(21) Appl. No.: 18/756,825

(22) Filed: Jun. 27, 2024

(51) Int. Cl. H01L 23/00; H01L 21/66

(52) U.S. Cl. CPC H01L 24/89; H01L 22/12; H01L 24/03; H01L 2224/03616; H01L 2224/89; H01L 2924/351

(57) ABSTRACT

A method of forming a bonded wafer, where the method includes receiving a first wafer including a first surface characteristic and a second wafer including a second surface characteristic; based on the first surface characteristic, performing a first location specific processing on the first wafer to obtain a first surface-to-be-bonded including a third surface characteristic; and bonding the first surface-to-be-bonded of the first wafer with the second wafer.

### TECHNICAL FIELD

The present invention relates generally to a method for bonding, and, in particular embodiments, to a method for bonding with location specific processing.

### BACKGROUND

Generally, integrated circuit (IC) devices reduce cost and complexity of electronic systems while increasing system performance and reliability by forming, in one monolithic structure, a circuit of multiple components coupled by several levels of wiring. The various circuit components (e.g., transistor, resistor, and capacitor) and interconnect elements (e.g., metal lines, contacts, and vias) are fabricated by processing a batch of semiconductor wafers through a fabrication process flow comprising a sequence of patterning levels. The monolithic structure gets constructed as a stack of layers as, at each patterning level, a layer in the substrate is patterned using lithography techniques, where multiple copies of a radiation pattern are printed in a rectangular array over a surface of the substrate before new layers are deposited for the next level of patterning. At the end of the fabrication process flow, a plurality of IC devices (referred to as dies) are fabricated in each wafer.

Having a bigger fraction of the system's functions performed by one IC device reduces system complexity but increases complexity of the IC fabrication process, thus increasing the unit cost of the IC. To be cost effective, IC devices are produced in separate broad categories such as electronic, photonic, and micro electro-mechanical systems (MEMS) ICs, or even functional sub-categories such as logic, memory, high voltage etc., so each IC fabrication flow uses compatible materials and processes in a reasonable number of patterning levels. Thus, a system may include multiple IC devices. However, having multiple ICs incurs a cost in complexity and performance resulting from remotely coupling each IC device to other devices by metal connectors and optical waveguides. This may be mitigated by using a three-dimensional (3D) stacked IC, formed by stacking several IC devices, each fabricated with a different process flow. A pair of IC devices in the 3D stacked IC may be bonded, using, for example, wafer bonding techniques such as fusion bonding and hybrid bonding. But, as expected, bonding IC devices for manufacturing 3D stacked ICs has its own set of challenges. Thus, further innovations in bonding technology are desired.

### SUMMARY

A method of forming a bonded wafer, where the method includes receiving a first wafer including a first surface characteristic and a second wafer; based on the first surface characteristic and a mapping model, calculate a bond wave propagation velocity during a bonding process of bonding the first wafer with the second wafer; performing a first location specific process on the first wafer to obtain a first activated surface-to-be-bonded, a parameter of the first location specific process being determined based on the bond wave propagation velocity; and bonding the first wafer including the first activated surface-to-be-bonded with the second wafer.

A method of forming a bonded wafer, where the method includes receiving a first wafer including a first surface characteristic and a second wafer including a second surface characteristic; based on the first surface characteristic, performing a first location specific surface activation processing on the first wafer to obtain a first activated surface-to-be-bonded including a third surface characteristic; and bonding the first wafer with the second wafer.

A method of forming a bonded wafer, where the method includes receiving a first wafer including a first surface characteristic and a second wafer including a second surface characteristic; based on the first surface characteristic, performing a first location specific processing on the first wafer to obtain a first surface-to-be-bonded including a third surface characteristic; and bonding the first surface-to-be-bonded of the first wafer with the second wafer.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 illustrates a plan view of a wafer surface to be bonded, in accordance with an embodiment of the invention;

FIGS. 2A-2B illustrate cross-sectional views of a wafer before and after a gas cluster beam (GCB) process with a location specific processing (LSP) feature configured to reduce across-wafer nonuniformity in copper recess, in accordance with an embodiment of the invention;

FIGS. 3A-3B illustrate cross-sectional views of a wafer before and after a gas cluster beam (GCB) process with a location specific processing (LSP) feature configured to reduce across-wafer nonuniformity in copper protrusion, in accordance with an embodiment of the invention; and

FIGS. 4-6 illustrate flowcharts of methods of forming a bonded wafer with a bonding flow using wafer-to-wafer (W2W) bonding, in accordance with some embodiments of the invention.

### DETAILED DESCRIPTION OF ILLUSTRATIVE EMBODIMENTS

In some integrated circuit (IC) fabrication flows, surfaces of two separate substrates are bonded to form a stacked structure. This disclosure describes a method for bonding surfaces, where surface preparation process steps prior to bonding include processing the surfaces-to-be-bonded with a location specific processing (LSP) tool. The embodiments of the method, utilize LSP to improve the bonding quality, as described in further detail in this disclosure. During the surface preparation processes of the bonding method disclosed herein, the bonding surface is modified by a localized flux of particles that interact with the surface materials. In general, the localized flux may be of various shapes, for example, the particles may be a beam within a spot on the surface or inside a narrow ribbon stretching linearly across the surface. A region of the surface may be exposed to the flux of particles by scanning the substrate through the beam or ribbon using a scanner, which may also be capable of rotating and tilting the substrate during scanning. The interaction between the surface and the flux of particles may be physical, such as in sputter etching, or chemical, or a combination of both. The particles may comprise electrons, atoms, ions, molecules, gas clusters, and the like. The advantages of using the described method stems from the LSP capability of the processing tool, which refers to a capability of controllably altering processing parameters locally. In other words, a controlled process parameter of an LSP process may be a function of coordinates of a location on the surface of the substrate. This allows the surface preparation processes to adjust the process conditions dynamically to achieve a desired surface characteristic, such as a desired surface topography (e.g., planarity, divot, and bump) or distribution of surface adhesion energy (i.e., surface activation).

In the embodiments in this disclosure, the surfaces to be bonded may be prepared using location specific gas cluster beam (GCB) planarization and surface activation processes in order to control surface properties relevant to the bonding process. As described further below, GCB process parameters (e.g., beam energy, scan rate, etc.) may be adjusted to spatially modulate properties (e.g., film thickness, strain, surface composition, etc.) related to surface topography and surface adhesion energy that affect characteristics of the bonding process, such as void formation, bond strength, and bond wave propagation (explained further below). Although the described embodiments have used LSP for GCB processes, it is understood that persons skilled in the art may apply the methods described in this disclosure to develop similar LSP processes using some other local surface preparation technique such as neutral particle beam, electron beam, ion beam (e.g., a monoatomic ion beam), and plasma torch processing. The particle flux may be generated using radio frequency (RF) plasma, microwave plasma, DC electric field, or a gas nozzle.

Bonding of two surfaces has several applications in IC fabrication. One example application is in a manufacturing process for silicon-on-insulator (SOI) substrates, where two unpatterned silicon wafers are joined by bonding a silicon surface of one wafer to a surface of a silicon oxide layer grown on the other wafer. Another area of application is integration schemes for fabricating three dimensional (3D) stacked ICs, where individual ICs from various wafers are joined together in a stack. Individual ICs of a stack may be referred to as a chiplet. The stack is built prior to coupling a packaging component (e.g., solder bump and redistribution layer (RDL)) to any chiplet.

In IC fabrication, bonding of two surfaces, such as for stacking two ICs, is achieved by executing a bonding flow, wherein the bonding flow may be categorized as die-to-die (D2D), die-to-wafer (D2W), or wafer-to-wafer (W2W).

In a D2D bonding flow, two singulated IC devices, or dies, are aligned to each other and their surfaces bonded using a bonding process. The D2D bonding flow provides an advantage of eliminating undesirable (or bad) dies by a priori testing and binning.

In the D2W bonding flow, one chiplet is aligned and bonded to another IC located on an unsingulated wafer. Multiple chiplets may be bonded to the same die on the wafer.

In the W2W bonding flow, two wafers are aligned and bonded together. Precise alignment may be needed if both wafers are patterned wafers. Each of the two wafers may have been processed through different fabrication process flows, but the sizes of the two wafers as well as the sizes of the respective dies being stacked have to match. Typically, wafers with high die yield are selected for W2W bonding since there is no opportunity to weed out bad dies a priori. After the bonding process is complete, each bonded wafer may be singulated to obtain individual 3D stacked ICs.

As mentioned above, the inventive aspects of the embodiments of the method for forming bonded areas pertains to preparing the surfaces-to-be-bonded for bonding. The surface preparation for bonding may include particle cleaning, planarization, and surface activation. The surface activation step may provide strong bonds between the surfaces, particularly if annealing the bonded interface is constrained to a relatively low temperature to avoid damaging the devices.

Irrespective of whether a D2D, D2W, or W2W bonding flow is used, a surface-to-be-bonded has to be prepared for the bonding process to achieve bonded areas having low void defects and low mechanical stress (to prevent bowing and other deformations). In this disclosure, we have described embodiments of the method for forming bonded areas in the context of the W2W bonding flow. Generally, in a W2W bonding flow for fabricating a 3D stacked IC, at least one of the two wafers is a patterned wafer. There are many established bonding processes available for various surface materials and industrial applications. Examples include fusion bonding, metal diffusion bonding, hybrid bonding (a combination of fusion and metal diffusion bonding), adhesive bonding, anodic bonding, eutectic bonding, and transient liquid phase diffusion bonding. Embodiments of the method, described in this disclosure, are described for bonding flows that use fusion bonding or hybrid bonding as the bonding process.

Although the example embodiments apply location specific GCB processing during pre-bonding surface preparation steps for fusion or hybrid W2W bonding, it is understood that a GCB process with LSP control may also be applied to surface preparation steps for D2W and D2D bonding.

One example of W2W bonding, where a patterned wafer is bonded to an unpatterned wafer, is a photonic IC (PIC) that integrates passive optical components with active optoelectronic components. In the example PIC, the passive components (e.g. waveguide and grating coupler) are built in silicon, whereas the active components (e.g., laser diode and photodetector) are built in an epitaxial InAs layer. To avoid process complexity, the passive components may be built in a silicon wafer to form a patterned first wafer, and the epitaxial InAs layer may be formed on an unpatterned second wafer. The two wafers are then bonded using fusion bonding, a bonding process explained in detail further below. After bonding, the InAs layer may be patterned to form the active components. Note that the two wafers need not be precisely aligned for bonding because the second wafer is unpatterned at the time of the bonding.

Another example of W2W bonding (or simply wafer bonding) is in an IC integration scheme for forming a 3D stacked IC, where each of the two surfaces-to-be-bonded is a surface of a patterned wafer. Prior to bonding, a first patterned wafer may have been processed to form an array of ICs comprising, for example, passive RF components (e.g., inductors, capacitors, and resistors), and a second wafer may have been processed to form a respective array of ICs having active RF circuitry configured to be coupled to the passive RF components. Each IC in a stack of two ICs has to be electrically coupled to the other in order to receive and transmit RF signals during operation. The coupling between the pair of ICs could be achieved using 3D packaging components such as solder bump and RDL and post-bond through-silicon via (TSV). However, it may be preferable to directly couple the two ICs, especially for high speed (or high frequency) connections, using hybrid bonding, a bonding process, where metal-to-metal bonds are formed (in addition to dielectric-to-dielectric bonds) during wafer bonding, as explained in detail further below.

A process integration flow for backside power delivery network (BS-PDN) integration is another example of using W2W bonding in IC fabrication. This example involves fusion bonding an unpatterned carrier wafer to the topside of a patterned wafer, in this instance a completed device wafer. With the topside attached to the carrier wafer, the device wafer may be turned upside down and the backside processed to fabricate a PDN. Here, topside refers to a side of the wafer that is patterned during fabrication of the device wafer while the backside refers to the opposite side of the same device wafer. The carrier wafer being an unpatterned wafer, the fusion bonding process does not require precise alignment. However, the process has to be controlled to limit mechanical stress generated by the bonding process because the BS-PDN integration is sensitive to bonded wafer distortion. If, after bonding to the carrier wafer, the patterned wafer is distorted excessively from its unbonded shape then proper lithographic alignment may not be achieved. When the backside of the patterned device wafer is etched to expose the device layers in order to build up the power delivery network proper contact will not be made to the pre-fabricated device. In some instances, higher order alignment corrections may be applied by the lithographic patterning tool to mitigate the alignment problem, but this is a time intensive process, which contributes to increased processing cost. Thus, reducing wafer distortion caused by the bonding process, especially the residual (non-linear) component, which is the most difficult to correct during patterning, is beneficial in enabling robust BS-PDN integration. As explained further below, the embodiments described in this disclosure, utilizes the LSP capability of GCB to control the bond wave propagation velocity by accounting for film thickness variations and pattern dependence of mechanical stress. Achieving a symmetric bond wave propagation, for example a bond wave initiated at the center progressing to the edge with a radially symmetric velocity pattern helps reduce additional stress generation during bonding, hence reducing the post-bonding distortion of the bonded wafers.

As mentioned above, the bonding processes used in the embodiments described in this disclosure are fusion bonding and hybrid bonding. Typically, fusion bonding is used to bond various combinations of dielectric and semiconductor surfaces (e.g., silicon oxide to silicon oxide or silicon to silicon oxide, and the like). Hybrid bonding is used when each of the surfaces-to-be-bonded includes a pattern of metal inlaid in a dielectric. In hybrid bonding, fusion bonding and metal diffusion bonding are combined to provide one bonding process for bonding metal-to-metal and dielectric-to-dielectric interfaces, as described in further detail below.

Fusion bonding is a process where two surfaces attracted by intermolecular forces (mainly van der Waals forces) adhere together spontaneously, that is, without any intermediate adhesive material; hence, fusion bonding is also known as direct bonding. As the gap between the wafers closes, bringing the respective surfaces within atomic distances, they are held together by forming chemical bonds between the interfacial atoms of the respective surfaces comprising, for example, a dielectric or semiconductor material. It is noted that the basic bonding mechanism between silicon-based materials is similar to that between two silicon wafers. A typical bonding flow for fusion bonding includes a sequence comprising surface preparation, a room-temperature bonding process (referred to as pre-bonding), and annealing at a higher temperature. The anneal process alters the interface chemistry to increase bond strength. Adequate bond strength may be needed to withstand, for example, a subsequent wafer thinning process such as backgrinding.

Intermolecular forces are mostly short-range forces and weaker than intramolecular forces, which are the ionic and covalent bonds that hold atoms together. With intermolecular forces being short-range forces, preparing clean and smooth surfaces for bonding is important for good bonding quality. Particles would space apart the two surfaces-to-be-bonded, thus creating unbonded areas (or voids). A micron size particle trapped in the interface may cause a void a centimeter wide. Various wet cleans (e.g., standard clean 1 (SC-1) and SC-2) as well as dry cleaning techniques may be used.

In addition to separation caused by particles, the surfaces may be separated because of asperities and micro-roughness. Thus, for spontaneous direct bonding, the bonding surfaces need to be very smooth, i.e., having root-mean-square (RMS) surface roughness less than about 0.5 nm and asperities less than about 2 nm. Planarization techniques such as chemical-mechanical polishing (CMP) and GCB planarization have been used to reduce surface roughness. Note that roughness refers to surface variation at short wavelength, characterized by short-range surface topography, as measured, for example, by atomic force microscopy (AFM). In contrast, surface variation at long wavelength is referred to as flatness, characterized by a total thickness variation (TTV) of the wafer. If, prior to bonding, a relatively thick layer is deposited (thick relative to surface variations due to roughness) then TTV may refer to a thickness variation of the deposited layer. Wafers having TTV of a few microns (e.g., one to three microns) may be bonded without creating unbonded areas. However, the wafers may be undesirably strained and deformed by the bonding process to accommodate the thickness variation. It is noted that incoming wafers may have existing strain and TTV variations due to prior processing that needs to be taken into account in estimating post-bonding strain. In the embodiments described in this disclosure, the LSP feature of the GCB tool may be utilized to adjust a GCB planarization process to modulate TTV.

The LSP feature of the GCB tool provides the ability of dynamically modulating the beam parameters such as a beam scan speed, gas cluster composition, tilt angle with the wafer, etc. as a function of beam location while scanning the wafer through the beam, as described in detail further below.

The LSP feature may be configured using strain and TTV wafer maps of incoming wafers, and the configuration may be optimized in order to optimize the topography of surfaces-to-be-bonded. The topography optimization may be done using, for example, wafer maps of post-bond TTV and strain characterization data in a feedback loop. The post-bond characterization data may include a bond wave propagation velocity, as described in detail further below.

The bond formation between a pair of aligned wafers may be initiated at some location, usually at the center, and, as soon as the surfaces come in atomic contact, bonds may start to form, even at room temperature. Within seconds, a “bond front” initiated, for example, at the center, spreads radially from the center to the edge to form a bonded wafer. The bond front is a periphery of the bonded area. The moving bond front, known as a bond wave, may be imaged using, for example, an infrared camera. A propagation velocity of the bond wave may be measured by infrared. In some embodiments of the bonding method described in this disclosure, the bond wave propagation velocity may be spatially modulated by GCB processing using LSP. In some embodiments, the bond wave propagation velocity may be obtained from a model using surface characteristics of the surfaces-to-be-bonded and measurements of post bonded wafer characteristics such as wafer shape, stress profile, and post-bonding alignment results.

As mentioned above, the spontaneously bonded wafer may be annealed at a high temperature. Unless a pre-bond surface activation step is performed, the anneal temperature may be, for example, between 700° C. to 1100° C., which may be unacceptably high for pre-processed wafers. A lower anneal temperature also helps reduce mechanical stress caused by mismatch in coefficient of thermal expansion (CTE). Various surface pre-treatments may enable achieving strong bonding at a lower anneal temperature; these include surface activation by atom bombardment, chemical-mechanical polishing (CMP), chemical surface treatment, ion implantation, plasma treatment, and surface treatment with GCB.

As known to persons skilled in the art, GCB processes may be used to modify surfaces of semiconductor substrates. The surface modification may be in the form of etching, cleaning, planarization, or deposition of films. Generally, the gas cluster beam comprises clusters of single or multiple gas species. The clusters can be described as nanometer-size agglomerates of gas species, which can range in size from a few to several thousand of molecules (e.g., about 10 to 10,000 particles in various embodiments) which are held together by weak forces (e.g., van der Waal forces).

The GCB surface treatment is similar to plasma treatment. However, there are some differences between exposing the wafer to an ion flux from plasma and exposing the wafer to GCB. For example, the ion flux from plasma comprises single monomer ions moving at high velocity, whereas the flux of charged clusters of the GCB comprises relatively slowly moving clusters of a large number of particles directed toward a spot of the wafer in a beam having a full width at half maximum (FWHM) of about 0.5 mm to about 30 mm, which is where most of the etching and surface activation occurs. The beam width being small compared to a diameter of a wafer enables the LSP feature of the GCB tool to control the beam in order to correct for long range systematic variations of a surface characteristic across the wafer. The LSP feature of the GCB tool is described in detail further below.

The surface pre-treatments (mentioned above) may alter the physicochemical state of the surface with a combination of physical and chemical interactions that include removing adsorbed material from the surface and controlling a surface density of dangling bonds created by breaking surface bonds. A dangling bond at one surface may become an active site for direct bonding with another surface. Furthermore, some of these treatments (e.g., CMP and GCB treatment) may reduce the surface roughness. Generally, the changes in the roughness and the physicochemical state of a dielectric or semiconductor surface results in increasing its surface adhesion energy. The detailed changes in the physicochemical state may be unknown, but it is known that wafers pre-treated with CMP and plasma activation have a faster bond wave propagation compared to films with plasma activation only. A plasma activation step may be needed after CMP to enable bonding, particularly when the maximum anneal temperature is limited. These results may be dependent on the CMP process conditions, consumables (pads, slurries etc.), and post-CMP cleaning chemistry. It is noted that, typically, CMP and plasma treatment systems do not provide LSP capability.

The embodiments described in this disclosure use GCB surface treatment processes that offer the planarization capabilities of the CMP tool in conjunction with the surface activation properties of the plasma activation process. The modulation of the GCB process parameters with LSP control enables location specific modulation of the bond wave propagation speeds. In the embodiments in this disclosure, the LSP feature of the GCB tool may be utilized to dynamically adjust a GCB surface treatment process parameter as the wafer is scanned through the beam in order to modulate the surface adhesion energy depending on the location of the incident beam, hence modulate the surface activation locally, thereby enabling location specific control of bond wave propagation speed.

The LSP feature may be configured using strain, wafer shape, and TTV wafer maps of incoming wafers, and the configuration may be optimized in order to optimize surface activation across the surfaces-to-be-bonded for optimum bonding quality. The optimization may be done using, for example, wafer maps of post-bond characterization data in a feedback loop. The post-bond characterization data may include the bond wave propagation velocity, either measured directly or calculated using a model based on other post-bond and pre-bond surface characterization data. The post-bond measurements may include wafer shape (e.g., curvature), mechanical stress, and optical alignment results (indicative of wafer distortion due to bonding).

Adhesion energy of an area of a surface is the energy per unit area available for the area to bond spontaneously with another surface. The surface adhesion energy can be modulated with a GCB by changing the roughness and physicochemical state on the dielectric surface. The bond wave propagation velocity (mentioned above) may be modulated by modulating the surface adhesion energy. A higher surface adhesion energy increases the speed of bond wave propagation while a lower surface adhesion energy decreases this speed. In order to reduce bonding-induced defects and wafer distortion, it is desirable that the bond wave propagates symmetrically from its point of initiation. For example, if the bonding is initiated at the center of the wafer then it is desired that the bond wave propagation velocity be radially symmetric, so the bond front is a circle progressing from the center to the edge of the wafer. Likewise, if the bonding is initiated at a spot on the circumference of the wafer then it is desired that the bond wave propagation velocity be axially symmetric about a major axis parallel to the bonding surface. However, asymmetry may be introduced, for example, by variations in surface topography such as bumps and divots in the path of the bond front affecting the bond wave speed. Generally, a bump slows down the bond wave and a divot speeds it up. Asymmetric bond wave propagation may also be a result of an asymmetric distribution of surface adhesion energy caused by asymmetric roughness and physicochemical state of the bonding surface. Asymmetry in bond wave propagation velocity may cause undesirable mechanical strain leading to distortion and alignment error. Since GCB processing modulates surface topography and surface activation (i.e., the surface physicochemical properties), the LSP feature of the GCB tool may be utilized to modulate the bond wave propagation velocity. Accordingly, a wafer map of bond wave propagation velocity (obtained from direct measurement or from a calibrated model) may be included in the post-bond characterization data used for the topography optimization and the surface activation optimization described above.

Furthermore, the bond wave propagation velocity near a wafer edge may be important for reducing edge defects in some bonding flows. Bonding compresses gas in the space between the wafers, thus creating a pressure gradient at the bond front. As the bond front approaches the edge of the wafer, the gas cools by a few degrees when it expands outward from a high pressure region to the lower pressure ambient of the processing chamber. The temperature drop, understood as the Joule-Thomson effect in thermodynamics, increases with increasing bond wave speed. For some conditions, the gas may be saturated with water vapor, and excessive bond wave speed at the wafer edge may cause water droplet formation. The water droplets may result in void defects near the wafer edge. However, using the LSP feature during the GCB surface activation, the surface adhesion energy and hence, the bond wave speed may be preferentially reduced in an edge region of the wafer to help reduce the edge defects. It is noted that surface adhesion energy is different from adherence energy. Adherence energy refers to an energy required to separate bonded wafers after annealing. Modulating surface adhesion energy to optimize surface activation and bond wave speed can have minimal effect on the final adherence energy of the wafer.

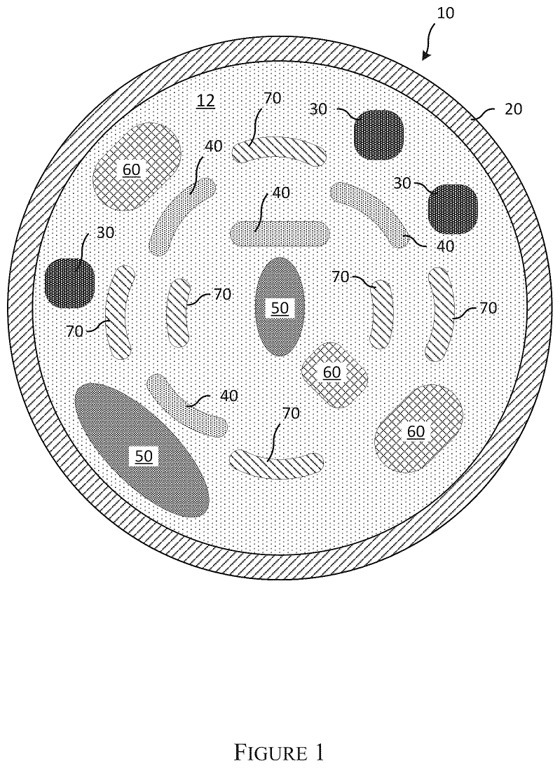

An innovative aspect of the bonding method described in this disclosure is applying LSP to modulate surface topography and surface adhesion energy (hence surface activation) during the pre-bond surface preparation steps. Location specific processing (as explained above) refers to controllably altering processing parameters locally, i.e., as a function of the coordinates (e.g., rectangular coordinates (x, y) of a location on the wafer surface being processed. Thus, (as also explained above) the described bonding method of utilizing LSP in preparing surfaces for bonding is applicable to any process that uses a local surface preparation technique, including the GCB processes described with reference to example embodiments. Application of the LSP concept to GCB processing of a surface to be bonded is explained with reference to a plan view of a wafer surface to be bonded, illustrated FIG. 1.

In FIG. 1, a wafer surface 10 is shown partitioned into seven non-overlapping regions. As illustrated in the plan view in FIG. 1, a region may comprise disconnected areas. Each region is marked with a specific pattern to indicate a respective set of GCB process parameter values with which the region would be processed. A set of GCB process parameters may include any number of process parameters under LSP control. Examples include beam composition, various gas flow rates, beam energy, beam current, beam width, wafer scan velocities in x-y directions, wafer twist angle (in-plane rotation), and wafer tilt angle (rotation of wafer surface relative to the beam). The background region 12 may be processed using a first set of GCB process parameter values. Regions 20, 30, 40, 50, 60, and 70 may be processed using a second, third, fourth, fifth, sixth, and seventh set of GCB process parameter values. No two regions may be processed identically. The LSP feature may be configured, (i.e., the process parameter values for each set of GCB process parameter values may be selected) based on incoming wafer surface characteristics and a model that provides the process parameter values for optimum processing. The model may be refined using post-bond characterization data.

It is understood that the example of location specific GCB processing described above with reference to FIG. 1 is not an exhaustive description of modifications that can be made to modulate the surface characteristics of the surface of a wafer to be bonded using LSP.

As mentioned above, hybrid bonding combines fusion bonding and metal diffusion bonding to provide a single bonding process to bond the metal-to-metal and dielectric-to-dielectric interfaces that occur when each of the surfaces-to-be-bonded includes a pattern of metal inlaid in a dielectric. In the hybrid bonding process, first the dielectric portions of the surfaces get pre-bonded (described above for the fusion bonding process) at a low temperature. The bonded wafer may be heated for an extended time, which serves two purposes. At the higher temperature, the fusion bond is annealed and metal diffusion bonding occurs between the metallic portions. The bond is a result of migration of metal atoms from one crystal lattice to the other during the bonding process. Since aluminum and copper interconnect may not tolerate high temperatures, a relatively low anneal temperature is used (e.g., about 250° C. to about 400° C.). Because of the low anneal temperature, the surface preparation for the surfaces-to-be-bonded typically includes a pre-bond surface activation step (e.g., a GCB surface activation process), as explained above.

Planarization of surfaces for hybrid bonding has to ensure void free bonding despite a material discontinuity between a dielectric and a metal region. In the commonly used damascene copper integration scheme, a pattern of openings etched in a planarized dielectric layer is filled with copper and polished back by a copper CMP process to remove excess copper from over the dielectric to form a pattern of inlaid metal bonding pads. The removal process generally leaves the copper surface recessed relative to the dielectric surface. On the average, the compressive force and thermal expansion of copper may bring the metal surfaces in atomic contact for metal diffusion bonding, but across-wafer nonuniformity of the metal recesses may cause void defects. Thus, the recess magnitude has to be stringently controlled across the wafer. Clearly, void defects may occur unless the CMP process provides shallow and uniform copper recess (in addition to providing a smooth and flat surface).

As mentioned above, the pair of patterned wafers may be precisely aligned prior to the hybrid bonding. In some IC designs, misalignment errors are mitigated by matching the copper bonding pads on one wafer with wider bonding pads on the other wafer. The wafer having the smaller pads are processed such that the copper surface protrudes a controlled height above the dielectric surface (as opposed to the wider pads, where the copper is recessed below the dielectric surface). The protrusion height has to be stringently controlled across the wafer. Otherwise, a tall metal protrusion may space apart the dielectric surfaces, causing voids near the metal-dielectric boundary. Thus, for the wafer having pads protruding above the dielectric surface, small and uniform copper protrusion is needed for void-free dielectric-to-dielectric bonding.

The amount of recess (or protrusion) may be modulated by a GCB dielectric removal process using the LSP feature to locally adjust recesses and protrusions of inlaid metal features by etching the dielectric layer in which the metal is inlaid. This capability may be utilized to provide a more uniform recess (or protrusion) across the wafer. In some embodiments, the bonding method may include measuring wafer maps of post-CMP copper recess (or protrusion) of each surface-to-be-bonded. Based on these wafer maps, the LSP feature of a GCB dielectric removal process may be configured to reduce variations in recess and protrusion. Performing the GCB dielectric removal process prior to performing the hybrid bonding of two patterned wafers provides an advantage of reducing void defects.

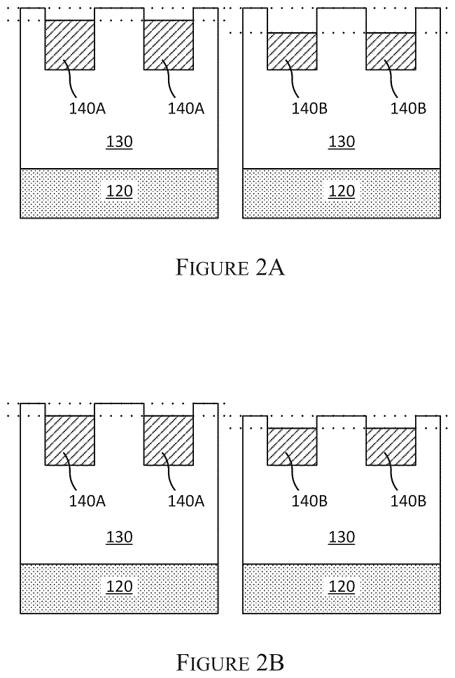

FIG. 2A illustrates two cross-sectional views of a post-CMP wafer showing the copper recess of the surface-to-be-bonded from two different regions of the wafer. The lower layers of the substrate are collectively shown as a substrate layer 120. A patterned dielectric layer 130 has been formed over the substrate layer 120. Copper bonding pads 140A, seen inlaid in the patterned dielectric layer 130, are from a region of the wafer shown on the left side in FIG. 2A. The copper bonding pads 140B from a different region of the wafer are shown on the right side in FIG. 2A. As illustrated in FIG. 2A, the region shown on the right side has a larger recess relative to the region shown on the left side. FIG. 2B illustrates the same two regions after the recess has been adjusted by a GCB dielectric removal process. Using the LSP feature, the patterned dielectric layer 130 in the region shown on the right side has been etched selective to that on the left side to equalize the copper recesses in these two regions, as illustrated in FIG. 2B.

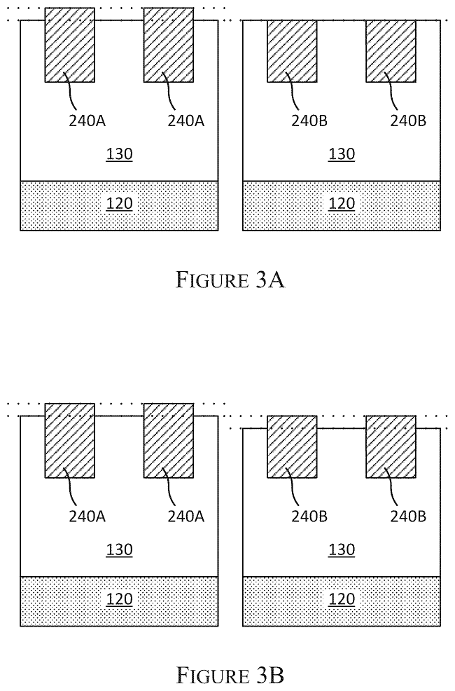

FIG. 3A and FIG. 3B illustrate an adjustment being done to equalize protrusions of copper bonding pads 240A to the protrusions of copper bonding pads 240B with a GCB dielectric removal process using the LSP feature, similar to the example described above with reference to FIG. 2A and FIG. 2B. As illustrated in FIG. 3A, the protrusions of the copper bonding pads 240A in the region shown on the left side are bigger than those of the copper bonding pads 240B in the region shown on the right side. As illustrated in FIG. 3B, using the LSP feature, the patterned dielectric layer 130 in the region shown on the right side has been etched selective to the left side to equalize the copper protrusions in the two regions.

As described above, in the embodiments of the bonding method, the LSP feature of the GCB tool may be utilized to modulate surface topography and distribution of surface adhesion energy during the pre-bond surface preparation steps. In various bonding flows using fusion bonding or hybrid bonding, modulating surface topography and surface adhesion energy may improve bonding quality and reduce defects by improving smoothness, flatness, uniformity of copper recess (or protrusion), strain, surface activation, and variation of bond wave propagation velocity. Some embodiments may be comprising a single GCB process step; some other embodiments may be comprising more than one GCB process step. For example, there may be a first GCB process for modulating surface topography and a second GCB process for modulating surface adhesion energy.

In the embodiments of the method for bonding, the LSP feature may be configured based on pre-bond characterization data of incoming wafers, and the configuration for a specific process flow may be optimized using post-bond characterization data in a feedback loop.

The pre-bond characterization data may include wafer maps of TTV, surface roughness, strain, wafer bow, and copper recess (or protrusion). In addition, the interconnect design layout may be taken into account in determining a configuration for the LSP feature prior to hybrid bonding. In addition to the metal features in the bonding layer, it may be necessary to include metal features in underlying layers, since underlying layers may also have large metal features that have surface topography that is transferred up the stack to the bonding layer to affect the bond wave propagation velocity.

The post-bond characterization data may include wafer maps of post-bond alignment error, strain, wafer bow, and bond wave propagation velocity, along with electrical results. Electrical results may include bonding yield, contact resistivity at Cu—Cu bonded interfaces and leakage current across bonded interfaces between dielectric films. The wafer map for bond wave propagation velocity may be obtained from direct measurement or from a calibrated model and wafer maps of other post-bond and pre-bond data, such as alignment error, strain, wafer bow, and interconnect layout. The model may be calibrated a priori based on historical measurements of bond wave propagation velocity obtained from controlled experiments. Machine learning processes may also be utilized to allow further improvement for future processes based on an analysis of the results of the bonding process. These characterizations and analyses can be performed on or in proximity to the bonding tool to allow continuous process improvement.

As mentioned above, the LSP feature of the GCB tool is the ability of dynamically modulating, for example, GCB dose or dwell time as a function of x-y or radial location while scanning the wafer through the beam. The GCB tool comprises a beam-line and a wafer scanner, which includes a low-pressure processing chamber. The beam-line is configured to produce a focused beam (i.e., the GCB) with dynamically adjustable beam parameters. The beam is directed into the processing chamber of the GCB tool. Typically, the beam is stationary while a wafer may be loaded and scanned through the beam by the wafer scanner. However, it is also possible to steer the beam using electromagnetic fields. In some systems, the beam includes a carrier gas, which may be introduced to adjust a pressure to control cluster formation and cluster size. In some embodiments, depending on the target application, this carrier gas can be combined with a reactive gas. The clusters are ionized in the beam-line by electron bombardment, thus allowing electric and magnetic fields to be applied for accelerating and directing the gas cluster beam. An optional flow of a co-gas may be established, where the co-gas flows through the processing chamber of the GCB tool in close proximity to the wafer surface in a direction roughly orthogonal to the incoming beam. The co-gas increases the local pressure and collides with some of the gas clusters, disintegrating the clusters to molecular gas. Interaction of the co-gas with the GCB modifies the beam characteristics to provide advantages in GCB processing, for example, improving surface smoothness while retaining a high etch rate. The wafer scanner may be controlled to move the wafer linearly and rotationally in a plane parallel to the wafer surface, such that the wafer is scanned through the beam along a desired trajectory on the wafer surface. In addition, while scanning, the plane of the wafer surface may be tilted to vary a tilt-angle relative to the beam. The wafer scanner of the GCB tool is described in detail in U.S. Pat. No. 11,587,760 B2, which is included in its entirety by reference with this application. In some embodiments, a stand-alone GCB tool may be used with a queue time control to the bonding tool. In some other embodiments, a GCB scan may be performed in situ in the bonding tool.

The LSP feature of the GCB tool is configured with a vector map of GCB process parameters. Here, a vector map of GCB process parameters refers to a mapping of location (x-y coordinates) on a wafer surface to GCB parameter values. The GCB process parameters used in the embodiments of this disclosure are those that affect the surface topography or the surface adhesion energy or both. Examples include composition of the beam (i.e., a cluster gas and a carrier gas), various gas flow rates, beam energy (accelerating voltage), beam current, beam width (diameter), wafer scan velocities in x-y directions, wafer twist angle (in-plane rotation), and wafer tilt angle (rotation of wafer surface relative to the beam).

In various embodiments, the cluster gas may be CF₄, NF₃, C₄F₈, CH₂F₂, CH₃F, or CHF₃, and the carrier gas may be Ar, N₂, or O₂. Typically, the beam comprises only one cluster gas and one carrier gas for a specific GCB process. The flow rates may be about 5 sccm to about 50 sccm for the cluster gas and about 50 sccm to about 500 sccm for the carrier gas. As described above, there may be a flow of a co-gas over the wafer surface, flowing roughly perpendicular to the GCB. In some embodiments, the co-gas may be an inert gas. In some embodiments, the co-gas may include reactants to modulate secondary reactions occurring near the wafer surface. In various embodiments, the co-gas comprises Ar, N₂, O₂, CF₄, NF₃, C₄F₈, CH₂F₂, CH₃F, CHF₃ and the like. A flow rate of the co-gas may be about 5 sccm to about 250 sccm.

The beam energy may be from about 1 kV to about 60 kV, the beam current may be from about 5 microamperes to about 500 microamperes, and the beam width (FWHM) may be about 0.5 mm to about 30 mm. The wafer scan velocities may be from about 50 mm/s to about 1500 mm/s. It is noted that scan velocity and beam width control a dwell time (beam exposure per unit area) which impacts a magnitude of surface activation. The wafer may be rotated in the plane of the surface; it follows that the twist angle may be any angle from 0° to 360°, where 0° may be referenced to a wafer notch. The wafer tilt angle (an angle relative to the beam) may be from 0° to about 65°, where 0° refers to the GCB being incident normal to the wafer surface.

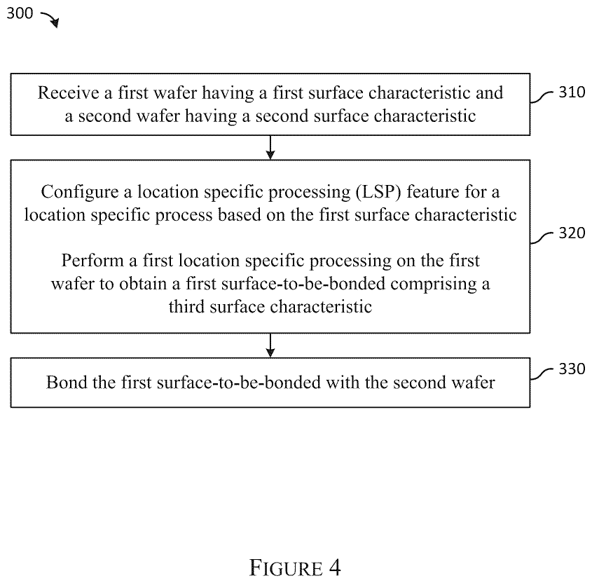

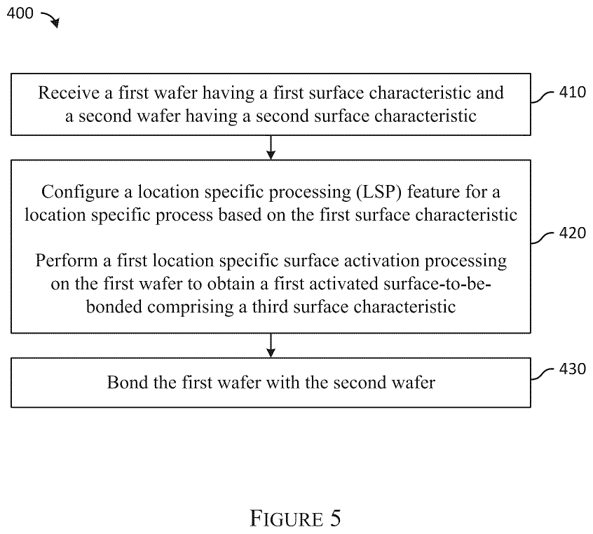

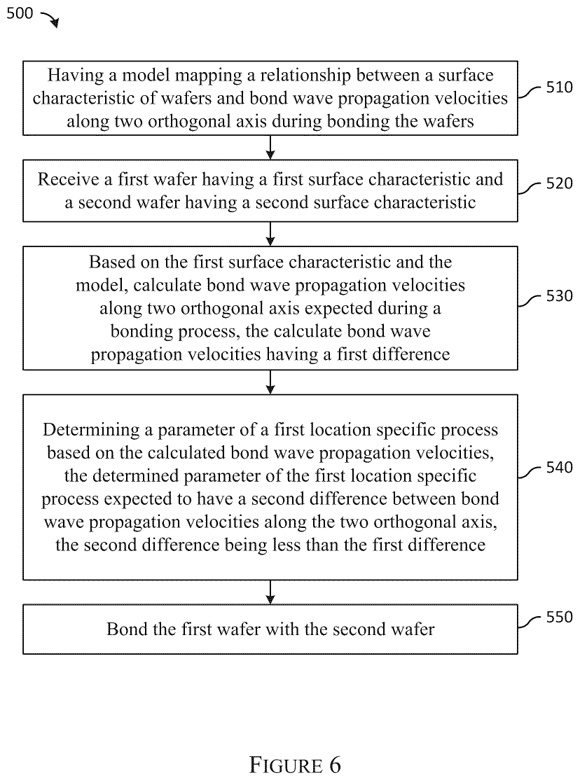

FIGS. 4-6 illustrate flowcharts of methods of forming a bonded wafer with a bonding flow using wafer-to-wafer (W2W) bonding. The flowchart illustrated in FIG. 4 summarizes the embodiments described above in a generalized method 300. The method 400 summarized by a flowchart illustrated in FIG. 5 modulates the surface activation with location specific processing, for example, using the LSP feature in a GCB surface treatment, as described above. FIG. 6 summarizes a method 500 using model-based calculations of bond wave propagation velocities to configure the LSP feature such that undesired nonuniformity in bond wave propagation velocity is reduced.

As illustrated in FIG. 4, the generalized method 300 is provided two wafers and respective surface characteristics. As indicated in box 310, a first wafer is received along with a first surface characteristic and a second wafer is received with a second surface characteristic. The first surface characteristic and the second surface characteristic are based on the pre-bond characterization data mentioned above. The pre-bond measurements may be analyzed to provide a surface characteristic such as a fingerprint or macro trends in TTV, strain, etc. Each surface characteristic may incorporate measurements of multiple metrics, for example, layer thickness, strain, and wafer bow. As indicated in box 320 of the method 300, a surface characteristic may be an input for a “machine” that calculates the vector map for location specific processing, for example, the vector map of GCB process parameters (as described above) to configure the LSP feature of a GCB tool, and the configured GCB tool may perform a GCB process using LSP on the surface of the first wafer. As expected, performing the GCB process using LSP modifies the surface of the wafer. i.e., alters the first surface characteristic of the first wafer to a third surface characteristic of a first surface-to-be-bonded, as indicated in box 320. In box 330, the first surface-to-be-bonded is bonded to the second wafer after the surface preparations are completed. In some embodiments, both the first wafer and the second wafer may be processed in this manner to obtain two surfaces-to-be-bonded, where the surface of the first wafer has the third surface characteristic and the surface of the second wafer has a fourth surface characteristic in preparation for bonding.

The machine providing the vector map for configuring the LSP feature of the processing tool, for example, the LSP feature of the GCB tool, may be using a model, for example, a mathematical model, algorithm, or a computational model to calculate the vector map of GCB parameters. As mentioned above, the vector map maps each location (x-y coordinates) of the wafer surface to a vector having GCB parameter values as vector components. In some embodiments, post-bond data may be acquired and used in a feedback loop to refine the model using some machine learning method.

FIG. 5 illustrates a flowchart for the method 400, where an activated surface-to-be-bonded is prepared by using location specific processing, for example, the LSP feature in a GCB surface treatment process. Similar to the method 300, a first wafer is received along with a first surface characteristic and a second wafer is received with a second surface characteristic. In addition to measurements of TTV and strain, the surface characteristics may include metrics that affect surface adhesion energy. Examples of surface characteristics may include surface topography (e.g., bumps and divots), underlying pattern density, chemical structures in the bulk and surface of the films that are to be bonded, and the bond wave propagation velocity (calculated using a calibrated predictive model). Similar to method 300, in method 400, the LSP feature of a GCB tool may be configured to modulate the surface adhesion energy, and the configured GCB tool may perform a GCB surface treatment process using LSP to obtain a first activated surface-to-be-bonded. The activated surface of the first wafer may have a third surface characteristic different from the first surface characteristic.

FIG. 6 illustrates a flowchart for a method 500, where a predictive model for calculating a wafer map of bond wave propagation velocity from a surface characteristic is used to reduce a bias between two components of the bond wave propagation velocities along two orthogonal directions (e.g., the x-y components of bond wave propagation velocity). The method 500 may be applied to improve, for example, a bonding flow having a known bias between the two components. The improvement is achieved by generating a vector map for configuring the LSP feature for a first location specific surface treatment process, for example, a first location specific GCB process where the vector map is adjusted to reduce the bias, and reducing the bias by performing the adjusted first GCB process on the surface of the first wafer.

As indicated in box 510 in FIG. 6, the method 500 has a model mapping a relationship between a surface characteristic of wafers being bonded and bond wave propagation velocities along two orthogonal axis during a bonding process.

In box 520, a first wafer is received along with a first surface characteristic and a second wafer is received with a second surface characteristic.

In box 530, based on the first surface characteristic, the predictive model is used to predict a first difference between the two orthogonal components assuming that the two incoming wafers are bonded without altering the surfaces of the first wafer and the second wafer.

In box 540, a GCB process parameter of the first GCB process with LSP is determined such that, assuming that the surface is processed using the first GCB process with the LSP configured to use the determined parameter, the predictive model predicts calculated bond wave propagation velocities having a second difference between the two orthogonal components, the second difference being less than the first difference. The first wafer is then processed with the first GCB process with the LSP configured to use the determined parameter.

In box 550, the first wafer is bonded with the second wafer.

Example embodiments of the invention are described below. Other embodiments can also be understood from the entirety of the specification as well as the claims filed herein.

Example 1. A method of forming a bonded wafer, where the method includes receiving a first wafer including a first surface characteristic and a second wafer including a second surface characteristic; based on the first surface characteristic, performing a first location specific processing on the first wafer to obtain a first surface-to-be-bonded including a third surface characteristic; and bonding the first surface-to-be-bonded of the first wafer with the second wafer.

Example 2. The method of example 1, further including: forming backside metallization on a first side of the first wafer after the bonding, where the second side of the first wafer is bonded to the second wafer and includes active devices.

Example 3. The method of one of examples 1 or 2, where performing the first location specific processing includes changing a topography of a major surface of the first wafer having the first surface characteristic to the first surface-to-be-bonded including the third surface characteristic.

Example 4. The method of one of examples 1 to 3, where performing the first location specific processing includes changing a surface adhesion energy of a major surface of the first wafer having the first surface characteristic to the first surface-to-be-bonded including the third surface characteristic.

Example 5. The method of one of examples 1 to 4, where the first location specific processing is performed by changing parameters of a location specific processing (LSP) tool, the LSP tool configured to target a limited region of the first wafer with a beam of particles.

Example 6. The method of one of examples 1 to 5 where the LSP tool includes a beam of gas clusters and a mechanism to alter where on the wafer the beam is directed, the parameters of the LSP tool including a composition of a cluster gas, a gas flow rate, a beam current, a tilt angle of the first wafer relative to the beam, a scan velocity of the first wafer relative to the beam, an exposure profile, a beam width, a dwell time, or combinations thereof.

Example 7. The method of one of examples 1 to 6, further including performing, before the bonding, a second location specific processing to activate the first surface.

Example 8. The method of one of examples 1 to 7, where the first location specific processing is further based on the second surface characteristic.

Example 9. The method of one of examples 1 to 8, where the first location specific processing is further based on an interconnect design layout of the first wafer.

Example 10. The method of one of examples 1 to 9, further including utilizing a location specific processing tool to activate the first surface-to-be-bonded in preparation for bonding.

Example 11. The method of one of examples 1 to 10, further including based on the second surface characteristic, performing a second location specific processing on the second wafer to obtain a second surface-to-be-bonded including a fourth surface characteristic.

Example 12. The method of one of examples 1 to 11, further including: performing a chemical mechanical planarization process prior to receiving the first wafer.

Example 13. The method of one of examples 1 to 12, further including: prior to receiving the first wafer, measuring, across the first wafer, a thickness of an outermost layer of the first wafer to obtain the first surface characteristic.

Example 14. The method of one of examples 1 to 13, further including: performing a chemical mechanical planarization process prior to receiving the first wafer; and measuring, across the first wafer, a depth of recesses on an outermost surface of the first wafer to obtain the first surface characteristic.

Example 15. A method of forming a bonded wafer, where the method includes receiving a first wafer including a first surface characteristic and a second wafer including a second surface characteristic; based on the first surface characteristic, performing a first location specific surface activation processing on the first wafer to obtain a first activated surface-to-be-bonded including a third surface characteristic; and bonding the first wafer with the second wafer.

Example 16. The method of example 15, further including performing a second location specific surface processing to change a topography of a major surface of the first wafer so as to form the first wafer with the first surface characteristic.

Example 17. The method of one of examples 15 or 16, where the first location specific surface activation includes a gas cluster beam process, local ion beam process, or a local plasma process.

Example 18. The method of one of examples 15 to 17, where the first location specific surface activation processing is further based on the second surface characteristic.

Example 19. The method of one of examples 15 to 18, further including based on the second surface characteristic, performing a second location specific surface activation processing on the second wafer to obtain a second surface-to-be-bonded including a fourth surface characteristic.

Example 20. The method of one of examples 15 to 19, further including: performing a chemical mechanical planarization process prior to receiving the first wafer; and measuring, across the first wafer, a thickness of an outermost layer of the first wafer to obtain the first surface characteristic.

Example 21. The method of one of examples 15 to 20, further including: performing a chemical mechanical planarization process prior to receiving the first wafer; and measuring, across the first wafer, a depth of recesses on an outermost surface of the first wafer to obtain the first surface characteristic.

Example 22. A method of forming a bonded wafer, where the method includes receiving a first wafer including a first surface characteristic and a second wafer; based on the first surface characteristic and a mapping model, calculate a bond wave propagation velocity during a bonding process of bonding the first wafer with the second wafer; performing a first location specific process on the first wafer to obtain a first activated surface-to-be-bonded, a parameter of the first location specific process being determined based on the bond wave propagation velocity; and bonding the first wafer including the first activated surface-to-be-bonded with the second wafer.

Example 23. The method of example 22, where the first location specific process includes a local ion beam process or a local plasma process.

Example 24. The method of one of examples 22 or 23, where the determined parameter of the first location specific process includes a composition of a cluster gas for a gas cluster beam (GCB), a gas flow rate, a beam current, a tilt angle of the first wafer relative to a GCB beam, a scan velocity, an exposure time, a GCB beam width, a dwell time, or combinations thereof.

Example 25. The method of one of examples 22 to 24, further including, before bonding: determining a second parameter of a second location specific process based on the bond wave propagation velocity; and performing the second location specific process with the determined parameter on the second wafer to obtain a second activated surface-to-be-bonded, the bonding including bonding the first activated surface-to-be-bonded with the second activated surface-to-be-bonded.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method of forming a bonded wafer, the method comprising:
receiving a first wafer comprising a first surface characteristic and a second wafer comprising a second surface characteristic;
based on the first surface characteristic, performing a first location specific processing on the first wafer to obtain a first surface-to-be-bonded comprising a third surface characteristic; and
bonding the first surface-to-be-bonded of the first wafer with the second wafer.

2. The method of claim 1, further comprising:
forming backside metallization on a first side of the first wafer after the bonding, wherein the second side of the first wafer is bonded to the second wafer and comprises active devices.

3. The method of claim 1, wherein performing the first location specific processing comprises changing a topography of a major surface of the first wafer having the first surface characteristic to the first surface-to-be-bonded comprising the third surface characteristic.

4. The method of claim 1, wherein performing the first location specific processing comprises changing a surface adhesion energy of a major surface of the first wafer having the first surface characteristic to the first surface-to-be-bonded comprising the third surface characteristic.

5. The method of claim 1, wherein the first location specific processing is performed by changing parameters of a location specific processing (LSP) tool, the LSP tool configured to target a limited region of the first wafer with a beam of particles.

6. The method of claim 5 wherein the LSP tool comprises a beam of gas clusters and a mechanism to alter where on the wafer the beam is directed, the parameters of the LSP tool comprising a composition of a cluster gas, a gas flow rate, a beam current, a tilt angle of the first wafer relative to the beam, a scan velocity of the first wafer relative to the beam, an exposure profile, a beam width, a dwell time, or combinations thereof.

7. The method of claim 1, further comprising performing, before the bonding, a second location specific processing to activate the first surface.

8. The method of claim 1, wherein the first location specific processing is further based on the second surface characteristic.

9. The method of claim 1, wherein the first location specific processing is further based on an interconnect design layout of the first wafer.

10. The method of claim 1, further comprising utilizing a location specific processing tool to activate the first surface-to-be-bonded in preparation for bonding.

11. The method of claim 1, further comprising based on the second surface characteristic, performing a second location specific processing on the second wafer to obtain a second surface-to-be-bonded comprising a fourth surface characteristic.

12. The method of claim 1, further comprising:
performing a chemical mechanical planarization process prior to receiving the first wafer.

13. The method of claim 1, further comprising:
prior to receiving the first wafer, measuring, across the first wafer, a thickness of an outermost layer of the first wafer to obtain the first surface characteristic.

14. The method of claim 1, further comprising:
performing a chemical mechanical planarization process prior to receiving the first wafer; and
measuring, across the first wafer, a depth of recesses on an outermost surface of the first wafer to obtain the first surface characteristic.

15. A method of forming a bonded wafer, the method comprising:
receiving a first wafer comprising a first surface characteristic and a second wafer comprising a second surface characteristic;
based on the first surface characteristic, performing a first location specific surface activation processing on the first wafer to obtain a first activated surface-to-be-bonded comprising a third surface characteristic; and
bonding the first wafer with the second wafer.

16. The method of claim 15, further comprising performing a second location specific surface processing to change a topography of a major surface of the first wafer so as to form the first wafer with the first surface characteristic.

17. The method of claim 15, wherein the first location specific surface activation comprises a gas cluster beam process, local ion beam process, or a local plasma process.

18. The method of claim 15, wherein the first location specific surface activation processing is further based on the second surface characteristic.

19. The method of claim 15, further comprising based on the second surface characteristic, performing a second location specific surface activation processing on the second wafer to obtain a second surface-to-be-bonded comprising a fourth surface characteristic.

20. The method of claim 15, further comprising:
performing a chemical mechanical planarization process prior to receiving the first wafer; and
measuring, across the first wafer, a thickness of an outermost layer of the first wafer to obtain the first surface characteristic.

21. The method of claim 15, further comprising:
performing a chemical mechanical planarization process prior to receiving the first wafer; and
measuring, across the first wafer, a depth of recesses on an outermost surface of the first wafer to obtain the first surface characteristic.

22. A method of forming a bonded wafer, the method comprising:
receiving a first wafer comprising a first surface characteristic and a second wafer;
based on the first surface characteristic and a mapping model, calculate a bond wave propagation velocity during a bonding process of bonding the first wafer with the second wafer;
performing a first location specific process on the first wafer to obtain a first activated surface-to-be-bonded, a parameter of the first location specific process being determined based on the bond wave propagation velocity; and
bonding the first wafer comprising the first activated surface-to-be-bonded with the second wafer.

23. The method of claim 22, wherein the first location specific process comprises a local ion beam process or a local plasma process.

24. The method of claim 22, wherein the determined parameter of the first location specific process comprises a composition of a cluster gas for a gas cluster beam (GCB), a gas flow rate, a beam current, a tilt angle of the first wafer relative to a GCB beam, a scan velocity, an exposure time, a GCB beam width, a dwell time, or combinations thereof.

25. The method of claim 22, further comprising:
before bonding, determining a second parameter of a second location specific process based on the bond wave propagation velocity; and
performing the second location specific process with the determined parameter on the second wafer to obtain a second activated surface-to-be-bonded, the bonding comprising bonding the first activated surface-to-be-bonded with the second activated surface-to-be-bonded.
